(19) United States
(12) Patent Application Publication
(10) Pub. No.: US 2003/0107043 A1
(43) Pub. Date: Jun. 12, 2003

(54) High-melting-point oxide light source, conductive paste and exhaust gas filter

(75) Inventors: Shinichi Ikeda, Tsukuba-shi (JP); Yasumoto Tanaka, Tsukuba-shi (JP); Naoki Shirakawa, Tsukuba-shi (JP); Hiroshi Bando, Tsukuba-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: National Inst. of Advanced Ind. Science and Tech., Tokyo (JP)

(21) Appl. No.: 10/310,838

(22) Filed: Dec. 6, 2002

(30) Foreign Application Priority Data
Dec. 6, 2001 (JP) 2001-372410
Dec. 6, 2001 (JP) 2001-372496
Dec. 6, 2001 (JP) 2001-372497

(51) Int. Cl. H01L 27/15

(52) U.S. Cl. 257/79

(57) ABSTRACT

An electrically conductive high-melting-point oxide light source that can be used in an oxygen-containing atmosphere includes a sintered oxide having as an essential constituent an oxide of an element selected from the group consisting of ruthenium, iridium, rhodium and rhenium. It is used an oxygen-containing atmosphere at a temperature of not less than 1700° C. A high-melting-point conductive paste includes particles of a sintered oxide having as an essential constituent an oxide of an element selected from the group consisting of ruthenium, iridium, rhodium and rhenium, and a binder and solvent. An exhaust gas filter includes a powdered sintered oxide having as an essential constituent an oxide of an element selected from the group consisting of ruthenium, iridium, rhodium and rhenium, the powdered sintered oxide being applied to and baked on, or formed into a heating element and attached to, a surface of a diesel engine exhaust gas filter of ceramic to form a heating element.

### BACKGROUND OF THE INVENTION

1. Field of the Invention

The present invention relates to a high-melting-point oxide light source, conductive paste and exhaust gas filter using a sintered oxide of platinum or other noble metal element selected from the group consisting of ruthenium, iridium, rhodium and rhenium.

2. Description of the Prior Art

Of the conductive ceramic light sources that can be used in air, silicon carbide (SiC) has high emissivity (approximately 0.8). As a conductor that can be used in air, SiC is widely used, such as for heating elements in electric furnaces.

There are many silicon carbide infrared source products, such as the Silicon Carbide Source 80030 manufactured by Oriel instruments. There are other conductors that can be used for electric furnace heaters, such as molybdenum silicide (up to 1700°C.) and lanthanum chromite (up to 1899° C.). However, these are not suitable for light source applications due to the fact that they are semiconductors with a relatively high electrical resistance and a low emissivity. In air, SiC does not decompose and oxidize below 1800° C., and therefore can be used at up to around 1600° C. The Oriel products are rated for use at 900° C.

In order to emit light at high temperatures, a material has to be electrically conductive and have a high melting point and high decomposition temperature. In an atmosphere containing no oxygen, tungsten and graphite have a melting point of over 3000° C. Tungsten is widely used for making high-brightness filaments for car headlamps and the like.

However, in the presence of oxygen, such as in air, high-melting-point metals, such as tungsten and graphite, oxidize and become non-conductive at around 1000° C. With melting points of 2250° C., 2457° C. and 1963° C., respectively, iridium, rhodium, osmium each have a high melting point rivaling those of tungsten and molybdenum, and oxidize less readily than high-melting-point metals, such as tungsten and graphite. However, in an oxygen-containing atmosphere they do exhibit some oxidation and volatility, meaning that in an oxygen atmosphere they do not have the necessary stable electrical conductivity.

Platinum (Pt) and platinum-rhodium (Pt—Rh) (melting point of 1769° C.) are relatively stable in an oxygen-containing atmosphere, and with respect to electrical resistivity, are each substantially metallic, including with respect to temperature dependency. However, at about 0.3, the emissivity of these materials at around 1000° C. is very low and they are also very costly, which makes them impractical for use as light source materials.

In the present invention, as materials that do not undergo change at such temperatures, it is desirable to use a material containing an oxide of an element selected from the group consisting of ruthenium, iridium, rhodium and rhenium, especially an oxide of Sr or Ru, as a material that emits light in an oxygen-containing atmosphere. This is because in terms of cost per unit volume, a material that includes strontium and oxygen is cheaper than just a ruthenium metal, and also is relatively easy to work, having workability on a par with that of a known product of Sic.

Before now, there ham been no light source that could be used at or above 1700° C. in an ordinary environment, such as an oxygen-containing atmosphere. It is known that in relatively low frequency infrared regions, the intensity of radiation from a light source increases with the increase in the temperature of the source (Stefan-Boltzmann law). In order to avoid oxidation of such light source materials as tungsten, the material is sealed in a glass tube together with an inert gas. The glass absorbs the infrared rays, so in order to obtain powerful, low-frequency infrared rays, it has been necessary to use a high-melting-point conductive material that can be used in air.

Previous conductive paste products have comprised particles of single metals, such as silver, gold, palladium, copper and platinum, dispersed in resin. With the exception of copper, in air (an oxygen-containing atmosphere) these can only be used up to their melting points of around 1000° C. Copper readily oxidizes and therefore requires an oxygen-free atmosphere. With a melting point of around 1800° C., platinum can be used at temperatures of up to 1500° C., but at temperatures of up to 1000° C., it exhibits some surface oxidation.

Also, since the above pastes are used with a single metal, it is difficult to achieve the high dispersibility required of a paste. This is particularly so in an application, such as a semiconductor fabrication process in which the size of fabricated pattern features range from several micrometers to several tens of micrometers. In this case, the metal particles in the paste must be adequately smaller than this feature size. Due to the high surface-active nature of single metal particles, the particles tend to form clusters when dispersed in resin, so a different technique is required to attain the above objective.

When it has been desired to use conductive paste in air at or above a temperature of 1000° C., there has been no means of electrically contacting and physically and readily adhering components in electric heating furnaces, nuclear reactors, blast furnaces and aeronautical or rocket engines which reach temperatures exceeding 1000° C. Also, due to the above-mentioned high surface-active nature of the single metal particles used in the paste, the particles do not readily disperse, resulting in materials having microstructures that make it a problem to use the materials.

Moreover, the particulates that mainly comprise the black exhaust smoke put out by diesel engines used in cars are becoming an environmental problem in Japan and Europe. A number of car manufacturers and companies have been developing Diesel Particulate Filters (DPFs) to place between the engine and the muffler. The development phase has more or less finished and actual products are appearing on the market. Companies have been using cordierite (2MgO₂Al₂O₃.5SiO₂) or silicon carbide (SiC) filters to cleanse exhaust gases by adsorbing particulates. The heat resistance of SiC, in particular, which can be used in air at temperatures of up to 1700° C., has spurred its use in a number of products by Ibiden Co., Ltd., NGK Insulators, Ltd. and Isuzu Motors Limited. Because of its ability to conduct electricity in air, SiC is being extensively used for heating elements in electric furnaces and other such applications.

In the system used by Isuzu Motors, there are two SiC filters with separate beaters provided in parallel between engine and muffler. While one is collecting (the mostly carbon) particles, the other is using its heater to burn up and discharge the collected particles as carbon dioxide. The combustion temperature is approximately 900° C. In the case of cars made by Peugeot that use an Ibiden DPF, the DPF includes a catalyst that is added to facilitate combustion of the particles. There is no heater; instead, the heat of the exhaust gas is used to combust the particles. In each case, SiC is used for just the particle collection function of the filter, and a separate beater arrangement is used for the combustion of the collected particles

Other conductive materials that can be used for heating electric furnaces include molybdenum silicide (up to 1700° C.) and lanthanum chromite (up to 1800° C.). However, these are semiconductors having a relatively high electrical resistance that are not suitable for DPF applications since they become unstable in exhaust gases of diesel engines where the temperature is high and there are large amounts of oxygen and various reactive gases.

Tungsten and graphite have a high melting point, but in an ordinary oxygen-containing environment, such as air, at around 1000° C. tungsten and graphite oxidize and become insulators, losing their electrical conductivity. Iridium and noble metals, such as rhodium and osmium, have a high melting point rivaling that of tungsten and molybdenum (ruthenium: 2250° C.; iridium: 2457° C.; rhodium: 1963° C.), and are harder to oxidize than tungsten or graphite. However, in an oxygen-containing atmosphere they do exhibit some oxidation and volatility, making them unsuitable as a material that can be stably used at high temperatures in an oxygen-containing atmosphere.

Platinum (Pt) and platinum-rhodium (Pt—Rh) (melting point: 1769° C.) are relatively stable in an oxygen-containing atmosphere and exhibit a substantially metallic electrical resistivity, including with respect to temperature dependency. However, they are very costly when used as single metals, and in many cases they lose their catalytic function.

DPFs and other diesel engine filters need to be able to collect particles and to burn the particles. However, if cordierite and SiC are used as filter materials, it is required to adopt a heater for combusting the particles and a catalyst for reducing the combustion temperature. It is also necessary to prepare two or more filters to collect and burn the particles.

An object of the present invention is to provide a high-melting-point oxide light source that can be used at high temperatures, especially above 1700° C., in a general oxygen-containing environment, such as air.

A second object is to provide a conductive oxide paste or paste that can readily be used to form a thick layer that can electrically contact and adhere objects in air at or above a temperature of 1000° C.

A third object is to provide an exhaust gas filter able to collect particles and to combust the collected particles.

### SUMMARY OF THE INVENTION

To attain the first object, the present invention provides an electrically conductive high-melting-point oxide light source that can be used in an oxygen-containing atmosphere, comprising a sintered oxide having as an essential constituent an oxide of au element selected from the group consisting of ruthenium, iridium, rhodium and rhenium.

For the above, an oxide of any one of the elements, ruthenium, iridium, rhodium and rhenium, is formed that is stable in an oxygen-containing atmosphere. The oxide can be combined with an alkaline metal or alkaline earth metal, such as strontium, to create a more stable chemical bond to thereby provide a light source that can be used in air at a high temperature, particularly at a high temperature of 1700° C. or above.

To attain the second object, the present invention provides a conductive paste comprising particles of a sintered oxide having as an essential constituent an oxide of an element selected from the group consisting of ruthenium, iridium, rhodium and rhenium, and a binder and solvent.

The sintered oxide particles can include an oxide that contains ruthenium and strontium.

The oxides have an in-air melting point of 1800 to 2000° C., and of the conductive oxides, have a very high conductivity that is maintained up to a high temperature, resulting in a conductive paste that can be applied under high-temperature conditions.

To attain the third object, the present invention provides an exhaust gas filter comprising a powdered sintered oxide having as an essential constituent an oxide of an element selected from the group consisting of ruthenium, iridium, rhodium and rhenium, the sintered oxide powder being baked onto a surface (outer wall) of a diesel engine exhaust gas filter to form a heating element, or being formed into a heating element and attached to au outer wall of an exhaust gas filter.

The sintered oxide powder has an in-air melting of 1800 to 2000° C. and good conductivity and stability up to the melting point, resulting in an exhaust gas filter that is able simultaneously to collect and combust particles in an oxygen-containing exhaust gas in a high-temperature environment achieved using a continuous flow of electricity or other means.

Further features of the invention, its nature and various advantages will be more apparent from the accompanying drawings and following detailed description of the invention.

### BRIEF DESCRIPTION OF THE DRAWINGS

FIG. 1 is a diagram illustrating the relationship between electrical resistance and temperature of a bar of polycrystalline Sr₂RuO₄, based on measurements.

FIG. 2 shows the system for measuring the emission spectrum of the polycrystalline Sr₂RuO₄ used as a light source.

FIG. 3 shows a comparison between the emission spectra of Sr₂RuO₄ and SiC at a temperature of 900° C.

FIG. 4 is a perspective view of a diesel engine exhaust gas filter according to the present invention.

FIG. 5 illustrates the method of measuring the electrical resistance of the conductive paste of the present invention.

### DESCRIPTION OF THE PREFERRED EMBODIMENT

First, the high-melting-point oxide light source of this invention will be explained. The high-melting-point oxide light source comprises a sintered oxide of an oxide of platinum or other noble metal element selected from the group consisting of ruthenium, iridium, rhodium and rhenium. More specifically, it is a sintered oxide of an element selected from the group consisting of ruthenium, iridium, rhodium and rhenium, and more particularly is a Sr—Ru oxide comprising a sintered mixture of a Sr compound and Ru compound or Ru metal. When it is energized, its temperature becomes high with radiating light, making it an infrared light source, visible light source or high-brightness light emitter.

In this embodiment, sintered Sr₂RuO₄ was produced using strontium and ruthenium in the form of a carbonate and an oxide, but any form of compound can be used. It is preferable to use a powder having a particle size ranging from several tens of micrometers to several hundred micrometers, but the particle size is not critical provided the powders are well mixed. This also applies to the particle size distribution.

The oxide of the present invention, in the case of strontium and ruthenium, can be Sr₂RuO₄, Sr₃Ru₂O₇ or SrRuO₃ or the like, of which Sr₂RuO₄ was judged to be the most stable. In terms of cost, too, Sr_{RuO}₄ is preferable since it is the compound that contains the least ruthenium. The ultrahigh-melting-point oxide light source can be used in an oxygen-containing atmosphere at up to around 2000° C., and can of course also be used in a reducing atmosphere. The invention is not limited to ruthenium. Insofar as oxides of the high melting-point metals, rhodium, iridium and rhenium, contain strontium and other such alkaline metals or alkaline earth metals, so providing the material having a high melting point, they also can be used to resolve the above problems.

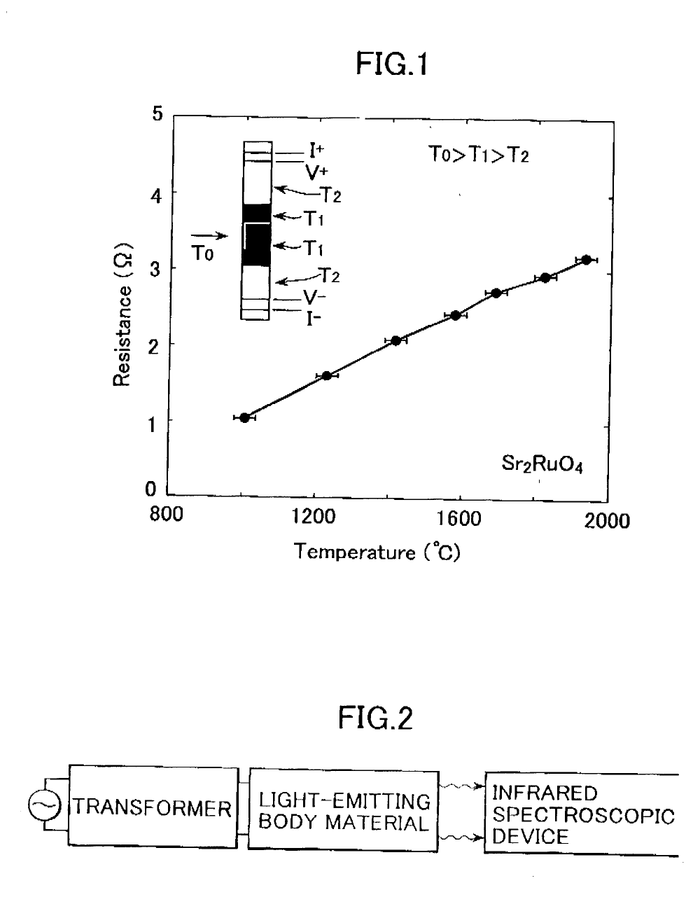

The above Sr₂RuO₄ has an in-air melting point of 2000° C., the highest melting point among conductive oxides, and shows good electrical conductivity up to the melting point. In FIG. 1, I+ and I− denote current terminals, V+ and V− denote voltage terminals, T₀ is the core temperature of the sintered rod and T₁ and T₂ are temperatures around the rod. The temperature is plotted along the horizontal axis. The temperature of tie sintered rod is highest at the center and decreases as the distance from the center increases, therefore T₀>T₁>T₂. From the graph, it can be seen that by being electrically energized in a oxidizing atmosphere, Sr₂RuO₄ can be used as a light source up to a high temperature in the order of 2000° C.

When the above light source is an oxide containing ruthenium and strontium, it is preferable for the strontium and ruthenium to be mixed at a molar ratio of 2:1. The Sr—Ru oxide light source is produced by mixing together powdered Sr compound and Ru compound or Ru metal, sintering the mixture in air at 900° C. to 1300° C. to form a sintered body, pulverizing the sintered body to a powder, molding the powder, and again sintering it in air at 1000° C. to 1500° C.

The Sr—Ru sintered oxide can also be produced by using concentrated infrared radiation or the like to melt the components and recrystallizing the melt. As described above, the sintered oxide has high conductivity in an oxidizing atmosphere and a high melting point, and ohmic resistance up to that temperature, and can therefore be used as a light source in an oxidizing atmosphere.

Next, the conductive paste of the invention will be described.

In place of the particles of precious metals used in previous pastes, the present invention provides a conductive paste comprising particles of a sintered oxide having as an essential constituent an element selected from the group consisting of ruthenium, iridium, rhodium and rhenium. These oxides have an in-air melting point of 1800 to 2000° C., and of the conductive oxides, have a very high conductivity that is maintained up to a high temperature. In particular, Sr₂RuO₄ has a melting point of 2000° C. in air, the highest among conductive oxides, and maintains good electrical conductivity up to the melting point, as shown by FIG. 1.

In FIG. 1, I+ and I− are current terminals, V+ and V− are voltage terminals, T₀ is the core temperature of the sintered rod and T₁ and T₂ are temperatures around the rod. The temperature is plotted along the horizontal axis. The temperature of the sintered rod is highest at the center and decreases as the distance from the center increases, thus, T₀>T₁>T₂. The binder used in the invention is selected from one, two or more inorganic substances or organic polymers. The inorganic substance is one or more selected from the group consisting of silica, alumina, titanium oxide, aluminum oxide, boron oxide, strontium oxide, zinc oxide, magnesium oxide, zirconium oxide, tin oxide, indium oxide and niobium oxide in the form of microparticles. Of these tin oxide, indium oxide and niobium oxide having high conductivity are advantageously used. The organic polymer is one or more selected from the group consisting of cellulose polymers (e.g., nitrocellulose, acetyl cellulose, cellulose acetate propionate, ethyl cellulose and benzyl cellulose), vinyl polymers (e.g., vinyl chloride, vinyl acetate and polyvinyl alcohol), polyester polymers (e.g., alkyd resin, maleic acid resin and polyethylene terephthalate), polyamide polymers (e.g., nylon 6, nylon 66 and nylon 6,10) and polyurethane polymers (e.g., polyether polyurethane and polyester polyurethane). When an inorganic binder is used, water can be used as the solvent, and when used with a water-soluble organic polymer, a water-based solution can be used, such as water-alcohol.

When an organic polymer is used, examples of solvents that can be used include aromatic solvents, such as benzene, xylene and toluene; alcohol-based solvents, such as methyl alcohol, ethyl alcohol and propyl alcohol; ketone solvents, such as methylethyl ketone; ether solvents; organic polar solvents, such as N-methylpyrrolidone, dimethylformamide and terpineol; and combinations of these.

The method of producing the conductive paste of the present invention will now be described. Paste staffing material containing an element selected from the group consisting of ruthenium, iridium, rhodium and rhenium is pulverized and sintered at approximately 1200° C. in air for 24 hours. The sintered material thus obtained is again pulverized and again sintered at 1300° C. for 24 hours to obtain the paste material. A solvent is then added to a binder and the mixture is heated and stirred to obtain a gelatinous binder. The binder is added to the paste material and the two are kneaded. To enable usage in air at temperatures above 1000° C., binder and paste powder are mixed in a ratio of 150 to 300 grams of paste powder to 100 grams of binder.

Finally, the exhaust gas filter of the present invention will be described. To form the exhaust gas filter, a powdered sintered oxide is prepared having as an essential constituent an oxide of an element selected from the group consisting of ruthenium, iridium, rhodium and rhenium. The sintered oxide powder is baked onto the surface (the outer wall) of a diesel engine exhaust gas filter to form a heating element, or is formed into a heating element and attached to the outer wall of the exhaust gas filter. The result is a device used, in an oxygen-containing atmosphere, for cleaning exhaust gases of diesel engines, with the filter having both the function of collecting particulates and the function of heating the particulates to combustion. An oxide of any one of the elements, ruthenium, iridium, rhodium and rhenium, is formed that is stable in an oxygen-containing atmosphere. By then combining the oxide with an alkaline metal or alkaline earth metal, such as strontium, a more stable chemical bond is achieved.

In the example of this embodiment, sintered Sr₂RuO₄ was produced using strontium and ruthenium in the form of a carbonate and an oxide, but any form of compound can be used. Although it is preferable to use a powder having a particle size ranging from several tens of micrometers to several hundred micrometers, the particle size is not critical provided that the powders are well mixed. This also applies to the particle size distribution. In the case of strontium and ruthenium, the oxide can be Sr₂RuO₄, Sr₃Ru₂O₇ or SrRuO₃ or the like. Among them Sr₂RuO₄ was judged to be the most stable. Sr₂RuO₄ is also preferable in terms of cost, since it is the compound that contains the least ruthenium. The ultrahigh-melting-point conductive exhaust gas filter can be used in an oxidizing atmosphere at up to around 2000° C., and can of course also be used in a reducing atmosphere. The invention is not limited to ruthenium. Insofar as oxides of the high melting-point metals, rhodium, iridium and rhenium contain strontium and other such alkaline metals or alkaline earth metals, so providing the material having a high melting point, they too can be used.

The Sr₂RuO₄ has an in-air melting point of 2000° C., the highest melting point among conductive oxides, and shows good electrical conductivity up to the melting point, as shown in FIG. 1. In FIG. 1, I+ and I− are current terminals, V+ and V− are voltage terminals, T₀ is the core temperature of the sintered rod and T₁ and T₂ are temperatures around the rod. The temperature is plotted along the horizontal axis of the graph. The temperature of the sintered rod is highest at the center and decreases as the distance from the center increases, so T₀>T₁>T₂. From the graph, it can be seen that by being electrically energized in an oxidizing atmosphere, Sr₂RuO₄ can be used as a diesel engine exhaust gas-cleaning device up to a high temperature of around 2000° C.

When the sintered oxide is to be applied as a heater by being baked onto the surface of a diesel engine exhaust gas filter, the sintered body material is pulverized and sintered in air for 24 hours at 900° C. to 1300° C. The sintered body thus formed is pulverized to a powder that is sintered in air at 1000° C. to 1500° C. The binder and solvent described with reference to the conductive paste are then used to prepare a solvent to which the sintered powder is added and mixed well to obtain a high-melting-point conductive paste. With reference to FIG. 4, a brush is used to apply the paste to an outer wall of a diesel engine exhaust gas filter 3 provided with exhaust gas entry cells 1 and exhaust gas exit cells 2, and the paste is sintered in air to form a heating element 4.

To use the sintered powder to produce an exhaust gas filter, the sintered powder is placed into a mold of a required shape and subjected to a pressure of 2000 to 5000 atmospheres to form it into a slab, which is again sintered at 900 to 1200° C. to obtain the exhaust gas filter. Thermosetting paste is used to bond the filter in place and enable it to be used to collect and combust particulates.

Examples of the invention will now be described. Examples 1 to 3 relate to a high-melting-point oxide light source, Examples 4 to 6 to a conductive paste, and Examples 7 and 8 to an exhaust gas filter.

### EXAMPLE 1

High-Temperature Electrical Characteristics of Sr_{RuO}₄ Oxide

Polycrystalline sintered Sr₂RuO₄ was produced as follows. SrCO₃ and RuO₂ were combined at a molar ratio of 2:1, thoroughly mixed in an agate mortar and sintered in air for 24 hours at 1200° C. The sintered body thus formed was pulverized to a powder that was press-formed into the shape of a bar 6 mm in diameter and 200 mm in length, which was sintered for three hours in air at 1300° C., producing a sintered bar of Sr₂RuO₄ oxide. The sintered bar of Sr₂RuO₄ oxide was placed in an air atmosphere in an infrared image furnace equipped with a halogen lamp and a rotating elliptical mirror. To measure the electrical resistance, silver paste was used to affix terminals to each end of the bar, and a radiation thermometer was used to measure the temperature at the portion T₀ heated to the highest temperature by the concentrated infrared radiation. In this state, a digital multimeter was used to measure the electrical resistance by the 4-terminal method while the lamp voltage was increased. The sintered bar of Sr₂RuO₄ started to melt when the temperature reached approximately 2100° C. As can be seen from FIG. 1, resistance rose with the increase in the temperature, but up to the melting point stayed at a metal-like value of between 1 and 3 ohms.

In FIG. 1, I+ and I− are current terminals and V+ and V− are voltage terminals. The temperature was not the same over the entire bar. The portion at which the concentrated infrared radiation produced the highest temperature was at the center of the bar, and it was the temperature T₀ at this point that was measured. The temperature was plotted along the horizontal axis of the graph. The temperature decreased as the distance from the center of the oxide increased, so that T₀>T₁>T₂. Thus, it was revealed that up to a high temperature of around 2000° C., the Sr₂RuO₄ could be used as a resistant heating element in an oxidizing atmosphere.

### EXAMPLE 2

Radiation Characteristics of Sintered Sr₂RuO₄

Polycrystalline sintered Sr₂RuO₄ was produced as follows. SrCO₃ and RuO₂ were combined at a molar ratio of 2:1, thoroughly mixed in an agate mortar and sintered in air for 24 hours at 1200° C. The sintered body thus formed was pulverized to a powder that was press-formed into the shape of a bar 6 mm in diameter and 200 mm in length, which was sintered for three hours in air at 1300° C., producing a bar of Sr₂RuO₄ oxide. This was subjected to a pressure of 3000 atmospheres, pressing the oxide into a bar-shaped specimen 5 mm in diameter and 10 cm long, which was sintered for 3 hours at 1000° C. Electrodes were attached to each end, in the form of stainless-steel sheets that were bonded to the specimen using thermosetting silver paste. FIG. 2 shows the arrangement used for spectral measurements.

A voltage of 100 volts at 50 Hz was applied to beat the specimen using Joule heat. The specimen started to glow when the temperature reaches 500° C. It was possible to raise the temperature of the specimen to 1500° C. The temperature of luminous portions was measured with a radiation thermometer (with respect to light having a wavelength of 1 μm). The emissivity of the specimen was measured separately, and found to be approximately 0.8 within the temperature range of 500 to 1000° C. Therefore, an emissivity of 0.8 was derived when the temperature was measured with the radiation thermometer. In principle, electrical heating can be used to elevate the temperature to just below the melting point (about 1900° C.).

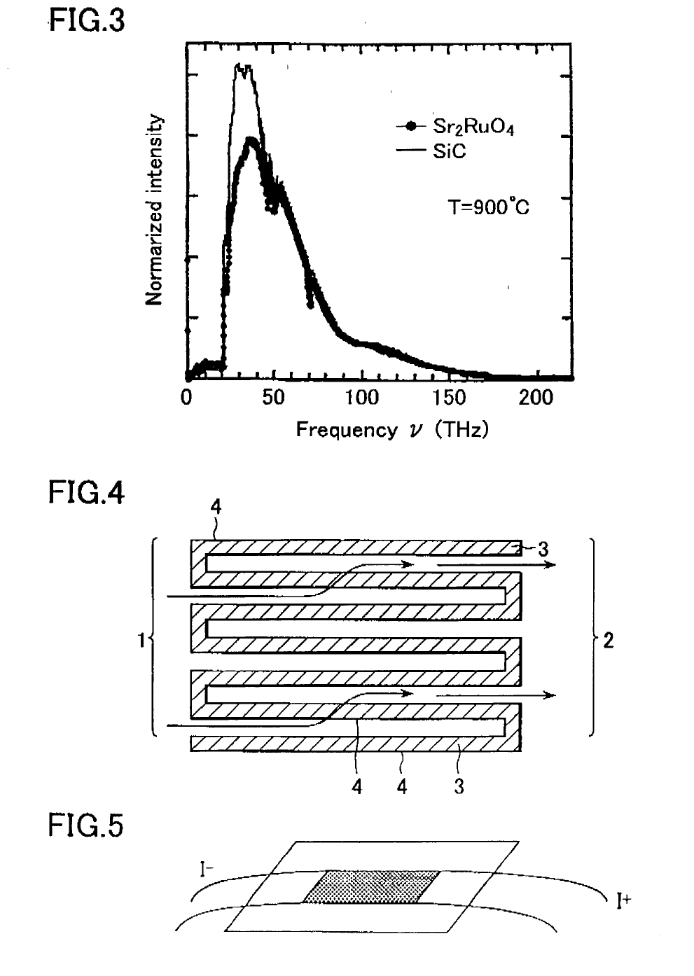

The spectrum of the light thus obtained was measured using an infrared spectrometer. For comparison, the same experiment was performed using a Silicon Carbide Source 80030 manufactured by Oriel. FIG. 3 shows the results. In each case the light source temperature was 900° C. The emissivity of the Oriel Silicon Carbide Source 80030 was also measured to compare the spectral intensity. The result was that the emissivity was found to be substantially the same as that of the polycrystalline SrRuO₄. This showed that at the same 900° C., the polycrystalline Sr₂RuO₄ radiated light at the same intensity as SiC.

### EXAMPLE 3

Production of Sr₂RuO₄ Single-Crystal for the Light Source

As in Example 1, a sintered bar of Sr₂RuO₄ was placed in an air atmosphere in an infrared image furnace equipped with a halogen lamp and a rotating elliptical mirror. The bar was suspended from the upper part of the furnace, and the lamp voltage was increased to heat the lower end of the bar to 2100° C. to melt the oxide. The end was then brought into contact with a sintered bar having the same Sr₂RuO₄ composition fixed in position in the lower part of the space, to thereby maintain the melted portion. In this state, the melted portion was then raised upwards at a speed of 20 mm/h to obtain Sr₂RuO₄ single-crystal. As in the case of polycrystalline Sr₂RuO₄, it was possible to use single-crystal Sr₂RuO₄ as a light source.

### EXAMPLE 4

Production of Paste

Polycrystalline Sr₂RuO₄ powder was produced as follows, to form the raw material for the high-melting-point conductive paste. SrCO₃ and RuO₂ were combined at a molar ratio of 2:1 and thoroughly mixed for 30 minutes in an agate mortar, then sintered in air for 24 hours at 1200° C. in an alumina crucible. The sintered body thus formed was pulverized to again form a powder that was mixed and again sintered for 24 hours in air at 1300° C. to obtain Sr₂RuO₄ powder. The powder was then ground in an agate mortar and passed through a screen to obtain powder having a particle diameter not exceeding 5 micrometers.

A liquid resin binder for the paste was then prepared by using ethyl cellulose as the resin and terpineol as a solvent, at a weight-ratio of 1:4. These were put into a beaker and stirred with a spatula, then heated at 50° C. for 3 hours. The mixture was then again stirred with a spatula and heated at 50° C. for 2 hours to thereby obtain a clear, gelatinous liquid resin binder. 20 grams of this liquid resin binder was then mixed with 60 grams of the Sr₂RuO₄ powder and the mixture kneaded for 6 hours in a three-roll mill, to thereby obtain high-melting-point conductive paste. A coating of the paste was applied to an alumina substrate (10 mm square and 1 mm thick) and four iridium wires were affixed at each end of the paste on the substrate. The paste was then baked at 500° C. for 5 minutes in air, and then sintered in air for 15 minutes at 1200 to 1300° C.

FIG. 5 illustrates the method of measuring the electrical resistance of the conductive paste. The in-air electrical resistance of the layer of paste sintered on the substrate was measured at 1000 to 1500° C. by the 4-terminal method. The high temperature of the substrate was measured inside a muffle furnace heated by a MoSiC heater element. The resistance increased in a metal-like fashion with the increase in temperature, from 1 mΩ to 2 mΩ.

### EXAMPLE 5

Production of Paste

60 grams of Sr₂RuO₄ powder was mixed with inorganic binder material consisting of 10 grams of aluminum oxide and 5 grams of zinc oxide, and these were mixed for 6 hours in a three-roll mill to obtain high-melting-point conductive paste. A coating of the paste was applied to an alumina substrate (10 mm square and 1 mm thick) and four iridium wires were affixed at each end of the paste on the substrate, and the paste was baked at 500° C. for 5 minutes in air and then sintered in air for 15 minutes at 1000 to 1100° C. The electrical resistance was measured by the same method used in Example 4 and was found to range from 0.5 mΩ to 0.8 mΩ, exhibiting a metal-like increase with the rise in temperature.

### EXAMPLE 6

Production of Paste

15 grams of the binder resin used in Example 4 was mixed with 60 grams of the Sr₂RuO₄ powder and inorganic binder material consisting of 5 grams of aluminum oxide and 5 grams of zinc oxide, and these were mixed for 6 hours in a three-roll mill to obtain high-melting-point conductive paste. A coating of the paste was applied to an alumina substrate (10 mm square and 1 mm thick) and four iridium wires were affixed at each end of the paste on the substrate, and the paste was baked at 500° C. for 5 minutes in air and then sintered in air for 15 minutes at 1100 to 1200° C. The electrical resistance was measured by the same method used in Example 4 and was found to range from 0.8 mΩ to 1.5 mΩ, exhibiting a metal-like increase with the rise in temperature.

### EXAMPLE 7

Paste Production for the Exhaust Gas Filter

Polycrystalline Sr₂RuO₄ powder constituting the paste powder was produced as follows. SrCO₃ and RuO₂ were combined at a molar ratio of 2:1 and finely ground for 30 minutes in an agate mortar, then sintered in air for 24 hours at 1200° C. in an alumina crucible. The sintered body thus formed was pulverized to again form a powder that was again sintered for 24 hours in air at 1300° C. to obtain the Sr₂RuO₄ powder. The powder was then ground in an agate mortar and passed through a screen to obtain powder having a particle diameter not exceeding 5 micrometers.

A liquid resin binder for the paste was then prepared by using ethyl cellulose as the resin and terpineol as a solvent at a weight-ratio of 1:4. These were put into a beaker, stirred with a spatula and then heated at 50° C. for 3 hours. The mixture was then again stirred with a spatula and heated at 50° C. for 2 hours to thereby obtain a clear, gelatinous liquid resin binder. 30 grams of this liquid resin binder was then mixed with 60 grams of the Sr₂RuO₄ powder and binder material consisting of 10 grams of boron oxide, 5 grams of aluminum oxide and 5 grams of zinc oxide and the mixture was kneaded for 6 hours in a three-roll mill, to thereby obtain the high-melting-point conductive paste.

Baking the Paste on the Exhaust Gas Filter

With reference to FIG. 4, a brush was used to apply the paste to the diesel engine exhaust gas filter 3 provided with exhaust gas entry cells 1 and exhaust gas exit cells 2, and the paste was sintered in air to form the heating element 4.

Exhaust Gas Filter Characteristics

The filter was installed between the diesel engine and the muffler, the engine was run for 1 hour and the particles in the exhaust gas discharged from the muffler were measured. At this time, the current flowing through the heating element was adjusted to adjust the filter temperature to 600° C. A filter provided with the Sr₂RuO₄ was found to collect approximately twice as many particles as a filter without the Sr₂RuO₄, showing the improvement in collection efficiency.

What is claimed is:

1. An electrically conductive high-melting-point oxide light source that can be used in an oxygen-containing atmosphere, comprising a sintered oxide having as an essential constituent an oxide of an element selected from the group consisting of ruthenium, iridium, rhodium and rhenium.

2. The light source according to claim 1, wherein the sintered oxide contains Ru and Sr.

3. The light source according to claim 2, wherein a molar ratio between the Sr and the Ru is substantially 2:1.

4. The light source according to claim 2, wherein the sintered oxide is Sr₂RuO₄.

5. The light source according to claim 2, wherein the sintered oxide is melted and recrystallized.

6. The light source according to claim 3, wherein the sintered oxide is melted and recrystallized.

7. The light source according to claim 4, wherein the sintered oxide is melted and recrystallized.

8. A method of producing a high-melting-point conductive Sr—Ru oxide light source, comprising the steps of mixing together powdered Sr compound and Ru compound or Ru metal to obtain a mixture, sintering the mixture in an oxygen-containing atmosphere at 900° C. to 1300° C. to form a sintered body, pulverizing the sintered body to a powder, molding the powder to form a molded powder, and again sintering the molded powder in an oxygen-containing atmosphere at 1000° C. to 1500° C.

9. The method according to claim 8, wherein further comprising the steps of melting the formed sintered body using concentrated infrared radiation to form a melt and recrystallizing the melt.

10. A high-melting-point conductive paste comprising particles of a sintered oxide having as an essential constituent an oxide of an element selected from the group consisting of ruthenium, iridium, rhodium and rhenium, and a binder and solvent.

11. The conductive paste according to claim 10, wherein the particles of the sintered oxide contain Ru and Sr.

12. The conductive paste according to claim 11, wherein the particles of the sintered oxide are Sr₂RuO₄.

13. The conductive paste according to claim 10, wherein the binder is at least one of an inorganic material and organic polymer.

14. The conductive paste according to claim 11, wherein the binder is at least one of an inorganic material and organic polymer.

15. The conductive paste according to claim 12, wherein the binder is at least one of an inorganic material and organic polymer.

16. The conductive paste according to claim 13, wherein the inorganic substance is one or more selected from the group consisting of silica, alumina, titanium oxide, aluminum oxide, boron oxide, strontium oxide, zinc oxide, magnesium oxide, zirconium oxide, tin oxide, indium oxide and niobium oxide.

17. The conductive paste according to claim 14, wherein the inorganic substance is one or more selected from the group consisting of silica, alumina, titanium oxide, aluminum oxide, boron oxide, strontium oxide, zinc oxide, magnesium oxide, zirconium oxide, tin oxide, indium oxide and niobium oxide.

18. The conductive paste according to claim 15, wherein the inorganic substance is one or more selected from the group consisting of silica, alumina, titanium oxide, aluminum oxide, boron oxide, strontium oxide, zinc oxide, magnesium oxide, zirconium oxide, tin oxide, indium oxide and niobium oxide.

19. The conductive paste according to claim 13, wherein the organic polymer is one or more selected from the group consisting of cellulose polymer, vinyl polymer, polyester polymer, polyamide polymer and polyurethane polymer.

20. The conductive paste according to claim 14, wherein the organic polymer is one or more selected from the group consisting of cellulose polymer, vinyl polymer, polyester polymer, polyamide polymer and polyurethane polymer.

21. The conductive paste according to claim 15, wherein the organic polymer is one or more selected from the group consisting of cellulose polymer, vinyl polymer, polyester polymer, polyamide polymer and polyurethane polymer.

22. An exhaust gas filter comprising a powdered sintered oxide having as an essential constituent an oxide of an element selected from the group consisting of ruthenium, iridium, rhodium and rhenium, the powdered sintered oxide being applied to and baked on a surface of a diesel engine exhaust gas filter of ceramic to form a heating element.

23. An exhaust gas filter comprising a powdered sintered oxide having as an essential constituent an oxide of an element selected from the group consisting of ruthenium, iridium, rhodium and rhenium, the powdered sintered oxide being formed into a heating element and attached to a surface of a diesel engine exhaust gas filter of ceramic.

24. The exhaust gas filter according to claim 22, wherein the heating element is an oxide containing Ru and Sr.

25. The exhaust gas filter according to claim 23, wherein the heating element is an oxide containing Ru and Sr.

26. The exhaust gas filter according to claim 24, wherein a molar ratio between the Sr and the Ru is substantially 2:1.

27. The exhaust gas filter according to claim 25, wherein a molar ratio between the Sr and the Ru is substantially 2:1.

28. The exhaust gas filter according to claim 24, wherein the heating element is Sr₂RuO₄.

29. The exhaust gas filter according to claim 25, wherein the heating element is Sr₂RuO₄.

30. An exhaust gas filter obtained through a method comprising the steps of mixing together powdered Sr compound and Ru compound or Ru metal to obtain a mixture, sintering the mixture in an oxygen-containing atmosphere at 900° C. to 1300° C. to form a sintered body, pulverizing the sintered body to a powder, molding the powder to form a molded powder, and again sintering the molded powder in an oxygen-containing atmosphere at 1000° C. to 1500° C. to form a Sr—Ru oxide as a heating element.

31. The exhaust gas filter according to claim 22, wherein the powdered sintered oxide is added to a medium comprising a binder and a solvent to form a paste, and the paste is applied to and baked on the surface of the diesel engine exhaust gas filter.

32. The exhaust gas filter according to claim 23, wherein the powdered sintered oxide is compressed into a heating element and attached to the surface of the diesel engine exhaust gas filter.
